(19) United States
(12) Patent Application Publication
(10) Pub. No.: US 2026/0018394 A1
(43) Pub. Date: Jan. 15, 2026

(54) CLUSTER TOOL

(71) Applicant: Tokyo Electron Limited, Tokyo (JP)

(72) Inventors: Dai KITAGAWA, Miyagi (JP); Koei ITO, Miyagi (JP); Taisei SEGUCHI, Miyagi (JP)

(73) Assignee: Tokyo Electron Limited, Tokyo (JP)

(21) Appl. No.: 19/332,070

(22) Filed: Sep. 18, 2025

Related U.S. Application Data
(63) Continuation of application No. PCT/JP2024/010444, filed on Mar. 18, 2024.

(30) Foreign Application Priority Data
Mar. 29, 2023 (JP) 2023-054292

(51) Int. Cl. H01J 37/32; H01L 21/67; H01L 21/687

(52) U.S. Cl. CPC H01J 37/32807; H01J 37/32642; H01L 21/67167; H01L 21/68707; H01J 2237/184

(57) ABSTRACT

A cluster tool includes a plasma processing apparatus, a mobile replacement apparatus, and control circuitry. The plasma processing apparatus includes a vacuum transfer module, a position detection sensor, and a plasma processing module including a support member, a consumable ring, and a lifter pin. The mobile replacement apparatus includes a ring storage portion that stores the consumable ring, and a ring replacement robot that transfers the consumable ring. The control circuitry executes a ring replacement sequence including connecting the mobile replacement apparatus to the plasma processing module, placing the consumable ring in the ring storage portion on the lifter pin, detecting a position of the consumable ring on the lifter pin, adjusting the position of the consumable ring on the lifter pin, and placing the consumable ring on a ring support surface.

### CROSS-REFERENCE TO RELATED APPLICATIONS

This application is a bypass continuation application of international application No. PCT/JP2024/010444 having an international filing date of Mar. 18, 2024 and designating the United States, the international application being based upon and claiming the benefit of priority from Japanese Patent Application No. 2023-054292, filed on Mar. 29, 2023, the entire contents of each are incorporated herein by reference.

### TECHNICAL FIELD

The present disclosure relates to a cluster tool.

### BACKGROUND

PTL 1 discloses a component replacement system including a component storage apparatus that stores a consumable component before use, and a component replacement apparatus that connects a processing apparatus to the component storage apparatus and replaces a consumable component after use in the processing apparatus with the consumable component before use in the component storage apparatus.

### CITATION LIST

### Patent Documents

PTL 1: JP2021-176173A

### SUMMARY

A technique according to the disclosure provides a cluster tool that can properly transfer a consumable component to a plasma processing module regardless of a docking error between the plasma processing module and a mobile replacement apparatus.

An aspect of the disclosure provides a cluster tool including: a plasma processing apparatus, a mobile replacement apparatus, and control circuitry, in which the plasma processing apparatus includes a plasma processing module having a first surface and a second surface, a vacuum transfer module connected to the plasma processing module via the first surface, and a position detection sensor, the plasma processing module includes a support member having a substrate support surface and a ring support surface, a consumable ring disposed on the ring support surface, and a plurality of lifter pins configured to move in a vertical direction between a transfer position above the ring support surface and a standby position below the ring support surface, the vacuum transfer module includes a transfer robot configured to transfer the consumable ring between the plasma processing module and the vacuum transfer module, the mobile replacement apparatus includes a ring storage portion configured to store the consumable ring, and a ring replacement robot configured to transfer the consumable ring between the ring storage portion and the plasma processing module, the control circuitry is configured to control the plasma processing apparatus and the mobile replacement apparatus to execute a ring replacement sequence, and the ring replacement sequence includes connecting the mobile replacement apparatus to the plasma processing module via the second surface, transferring the consumable ring in the ring storage portion to the plasma processing module by the ring replacement robot and placing the consumable ring on the plurality of lifter pins at the transfer position, detecting a horizontal position of the consumable ring on the plurality of lifter pins by the position detection sensor, adjusting the horizontal position of the consumable ring on the plurality of lifter pins by the transfer robot based on a position detection result from the position detection sensor, and moving the plurality of lifter pins to the standby position and placing the consumable ring on the ring support surface.

According to the disclosure, it is possible to provide a cluster tool that can properly transfer a consumable component to a plasma processing module regardless of a docking error between the plasma processing module and a mobile replacement apparatus.

### BRIEF DESCRIPTION OF DRAWINGS

FIG. 1 is a plan view illustrating an example of a configuration of a substrate processing system according to an embodiment.

FIG. 2 is a perspective view illustrating an example of a configuration of a transfer robot of a vacuum transfer module.

FIG. 3 is a vertical sectional view illustrating an example of a configuration of the vacuum transfer module.

FIG. 4 is a vertical sectional view illustrating an example of a configuration of a plasma processing module.

FIG. 5 illustrates disposition of a lift pin.

FIG. 6 is a vertical sectional view illustrating an example of a configuration of a mobile replacement apparatus.

FIG. 7 is a vertical sectional view illustrating a connected state of the vacuum transfer module, the plasma processing module, and the mobile replacement apparatus.

FIG. 8 is a flow chart illustrating a flow of a ring replacement sequence according to the embodiment.

### DETAILED DESCRIPTION

A plasma processing apparatus that performs plasma processing such as an etching process or post-processing on a semiconductor substrate (hereinafter referred to as a “substrate”) uses various consumable components such as a ring assembly. Such a consumable component is replaced with a new consumable component when an amount of consumption is larger than a predetermined amount of consumption.

Such replacement of the consumable component is performed using a component replacement apparatus connected to the plasma processing apparatus each time the consumable component is replaced, as also disclosed in PTL 1. However, PTL 1 does not consider positional misalignment between the plasma processing apparatus and the component replacement apparatus at the time of docking, and thus there is room for improvement in this respect.

A technique according to the disclosure has been made in view of the above-described circumstances and provides a cluster tool that can properly transfer a consumable component to a plasma processing module regardless of a docking error between the plasma processing module and a mobile replacement apparatus. Hereinafter, a plasma processing system according to an embodiment will be described with reference to the drawings. The same reference numerals will be given to elements having substantially the same functional configurations throughout the specification and the drawings, and redundant description thereof will be omitted.

### <Plasma Processing System>

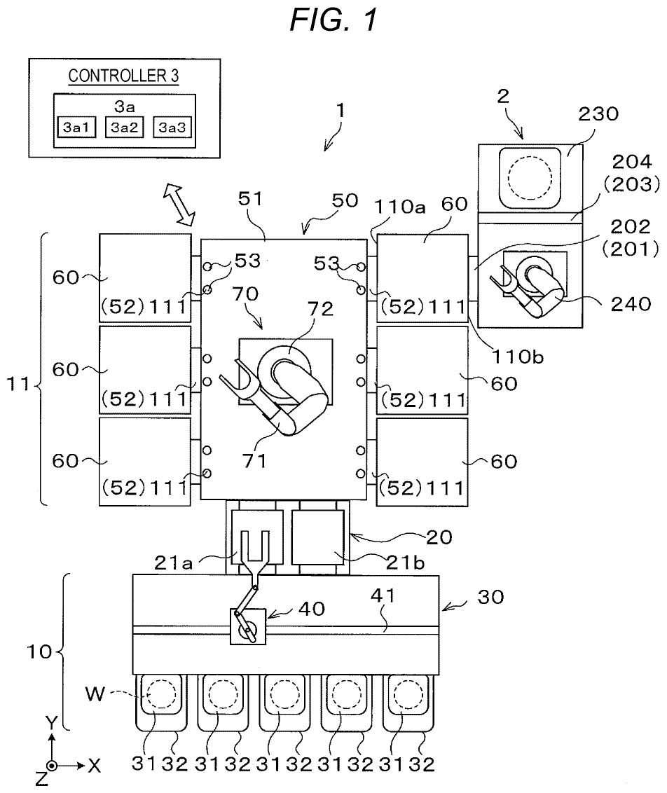

First, a configuration of the substrate processing system according to the present embodiment will be described. FIG. 1 is a plan view showing a schematic configuration of the plasma processing system of the present embodiment. The plasma processing system includes a plasma processing apparatus 1, a mobile replacement apparatus 2, and at least one controller 3 (i.e., control circuitry). As illustrated in FIG. 1, the plasma processing system is a cluster tool that includes a plasma processing module 60 and a vacuum transfer module 50, which will be described later. A wafer is an example of a substrate. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

As illustrated in FIG. 1, the plasma processing apparatus 1 has a configuration in which an atmospheric portion 10 and a reduced-pressure portion 11 are integrally connected through a load-lock module 20. The atmospheric portion 10 includes an atmospheric module that processes and/or transfers a substrate W under an atmospheric atmosphere. The reduced-pressure portion 11 includes a decompression module (vacuum module) that processes and/or transfers the substrate W in a decompressed (vacuum) atmosphere.

The load-lock module 20 has a plurality of, for example, two load-lock chambers 21a and 21b (hereinafter, may be collectively referred to simply as a “load-lock chamber 21”) in the embodiment along an atmospheric transfer module 30 to be described later and the vacuum transfer module 50 to be described later. The load-lock chamber 21 is configured to temporarily hold the substrate W.

The load-lock chamber 21 is provided to establish communication, through a substrate transfer port, between an atmospheric transfer space of the atmospheric transfer module 30 to be described later of the atmospheric portion 10 and a vacuum transfer space of the vacuum transfer module 50 to be described later of the reduced-pressure portion 11. The load-lock chamber 21 is configured such that the inside thereof can be switched between an atmospheric atmosphere and a decompressed atmosphere (vacuum state). That is, the load-lock module 20 is configured to appropriately transfer the substrate W between the atmospheric portion 10 in an atmospheric atmosphere and the reduced-pressure portion 11 in the decompressed atmosphere. The substrate transfer port is openable and closable by a gate valve (not illustrated).

The atmospheric portion 10 includes the atmospheric transfer module 30 including a substrate transfer robot 40 to be described later therein, and load ports 32 placed with hoops 31 capable of storing the substrates W. An orienter module (not illustrated) that adjusts an orientation of the substrate W in the horizontal direction, a storage module (not illustrated) that stores the substrates W, and the like may be provided adjacent to the atmospheric transfer module 30.

The atmospheric transfer module 30 includes a rectangular housing therein, and an interior of the housing is maintained in the atmospheric atmosphere. A plurality of, for example, five load ports 32 are disposed in parallel on one side surface forming a long side of the atmospheric transfer module 30 on a Y-axis negative direction side. The load-lock chambers 21a and 21b of the load-lock module 20 are disposed in parallel on the other side surface forming a long side of the atmospheric transfer module 30 on a Y-axis positive direction side.

The substrate transfer robot 40 that transfers the substrate W is provided inside the atmospheric transfer module 30. For example, the substrate transfer robot 40 is configured to move on a transfer path 41 extending in an X-axis direction and transfer the substrate W between the hoop 31 of the load port 32 and the load-lock chambers 21a and 21b of the load-lock module 20. A configuration of the substrate transfer robot 40 is not limited thereto.

The reduced-pressure portion 11 includes the vacuum transfer module 50 that transfers the substrate W therein, and the plasma processing module 60 that performs desired processing on the substrate W transferred from the vacuum transfer module 50. The inside of each of the vacuum transfer module 50 and the plasma processing module 60 can be maintained in a reduced-pressure (vacuum) atmosphere. In the embodiment, a plurality of, for example, six plasma processing modules 60 and two load-lock chambers 21a and 21b are connected to one vacuum transfer module 50. The number and disposition of plasma processing modules 60 are not limited to the embodiment, and may be set as desired.

The vacuum transfer module 50 includes a housing 51 having a planar rectangular shape. The housing 51 has a substrate transfer port 52 to which the plasma processing module 60 to be described later is connected. A vacuum transfer space 50s (see FIG. 3) of the vacuum transfer module 50 communicates with the inside of the plasma processing module 60 through the substrate transfer port 52.

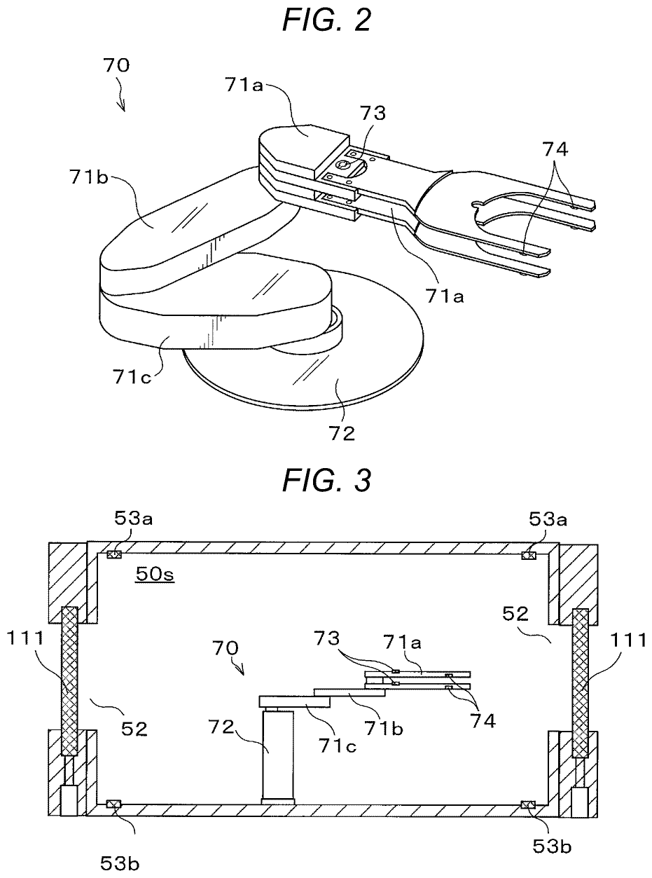

A transfer robot 70 that transfers the substrate W is provided inside the vacuum transfer module 50. As illustrated in FIG. 2, the transfer robot 70 is an articulated robot including a plurality of, for example, three transfer arms 71a to 71c. Each of three transfer arms 71 is pivotable. The transfer arm 71a at a distal end holds and transfers the substrate W or a consumable component. The transfer arm 71a at the distal end is also referred to as a so-called end effector and can simultaneously transfer two substrates W overlapped in a vertical direction. In other words, the transfer robot 70 has two transfer arms 71a disposed to overlap with each other in the vertical direction. The transfer arm 71c at a proximal end is pivotably attached to a base 72.

As illustrated in FIGS. 2 and 3, a first position detection sensor 73 and a second position detection sensor 74 are provided on an upper surface of a proximal end side (a side of connection with the transfer arm 71b) of the transfer arm 71a at the distal end, that is, the end effector, and a lower surface of a distal end side (a side where the substrate W or the consumable component is held) of the end effector, respectively. The first and second position detection sensors 73 and 74 are, for example, displacement meters. The transfer robot 70 can detect, by the first and second position detection sensors 73 and 74, a relative horizontal position of the substrate W or the consumable component relative to a support member 120 to be described later in the plasma processing module 60.

In one embodiment, the transfer robot 70 is configured to transfer the substrate W between the load-lock module 20 and one or a plurality of plasma processing modules 60. In addition, as will be described later, the transfer robot 70 temporarily holds the consumable component in the plasma processing module 60 and adjusts a position of the consumable component in a component replacement sequence.

Between the plasma processing module 60 and the vacuum transfer module 50 inside the vacuum transfer module 50, more specifically, in the vicinity of the substrate transfer port 52, a plurality of position detection sensors 53 are provided, in the embodiment, two for each substrate transfer port 52, for detecting a position of the substrate W or the consumable component on the transfer robot 70. In an example, the position detection sensor 53 includes a light emitting unit 53a and a light receiving unit 53b. As also illustrated in FIG. 3, the light emitting unit 53a is provided, for example, at a ceiling surface of the vacuum transfer module 50, and the light receiving unit 53b is provided, for example, at a bottom surface of the vacuum transfer module 50.

In the vacuum transfer module 50, it is detected (by the light receiving unit 53b) whether light emitted from the light emitting unit 53a of the position detection sensor 53 can be received by the light receiving unit 53b, thereby determining whether the substrate W or the consumable component is located immediately below the light emitting unit 53a, that is, in the vicinity of the substrate transfer port 52. In addition, by detecting light reception by each of the plurality of position detection sensors 53, a relationship of the relative horizontal position of the substrate W or the consumable component relative to the substrate transfer port 52 can be detected.

A type and a configuration of the position detection sensor are not particularly limited to the illustrated example, as long as the position of the substrate W or the consumable component on the transfer robot 70 can be detected. For example, the position detection sensor 53 may be configured such that the light emitting unit 53a and the light receiving unit 53b are integrated, or another sensor such as a length measurement sensor may be used.

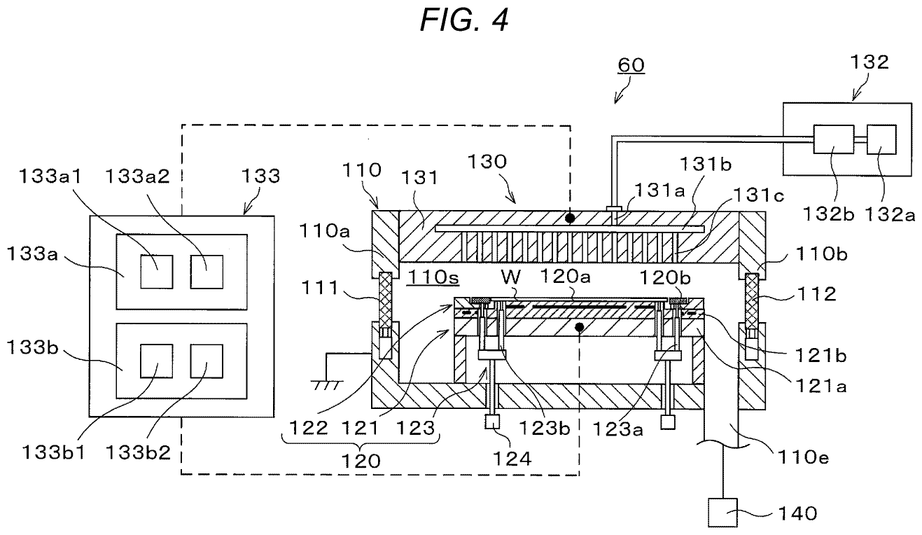

The plasma processing module 60 performs plasma processing such as an etching process on the substrate W. In one example, the plasma processing module 60 includes a plasma processing chamber 110, the support member 120, a plasma generator 130, and an exhaust system 140, as illustrated in FIG. 4.

The plasma processing chamber 110 has a plasma processing space 110s. The plasma processing chamber 110 (i.e., of the plasma processing module 60) has a first surface 110a and a second surface 110b on a side opposite to a side of the first surface 110a. A first opening 110c is formed in the first surface 110a, and the first opening 110c is connected to the vacuum transfer module 50 through the substrate transfer port 52. Accordingly, the plasma processing space 110s communicates with the vacuum transfer space 50s through the first opening 110c and the substrate transfer port 52. A gate valve 111 is provided on the first surface 110a side, and the substrate transfer port 52 is openable and closable by the gate valve 111. A second opening 110d is formed in the second surface 110b, and the second opening 110d is connected to the mobile replacement apparatus 2 to be described later through a component transfer port 201 to be described later. A gate valve 112 is provided on the second surface 110b side, and the component transfer port 201 is openable and closable by the gate valve 112.

The support member 120 includes a main body 121, a ring assembly 122, and a lifter 123. The main body 121 has a central region 120a for supporting the substrate W and an annular region 120b for supporting the ring assembly 122. The annular region 120b of the main body 121 surrounds the central region 120a of the main body 121 in a plan view. The substrate W is disposed on the central region 120a of the main body 121, and the ring assembly 122 is disposed on the annular region 120b of the main body 121 to surround the substrate W on the central region 120a of the main body 121. Accordingly, the central region 120a is also called a substrate support surface for supporting the substrate W, and the annular region 120b is also called a ring support surface for supporting the ring assembly 122.

In one embodiment, the main body 121 includes a base 121a and an electrostatic chuck 121b. The base 121a includes a conductive member. The conductive member of the base 121a may function as a lower electrode. The electrostatic chuck 121b is disposed on the base 121a. The electrostatic chuck 121b includes a ceramic member (not illustrated) and an electrostatic electrode (not illustrated) disposed in the ceramic member. The ceramic member has the central region 120a. In one embodiment, the ceramic member also has the annular region 120b. Other members that surround the electrostatic chuck 121b, such as an annular electrostatic chuck and an annular insulating member, may have the annular region 120b. In this case, the ring assembly 122 may be disposed on the annular electrostatic chuck or the annular insulating member, or may be disposed on both the electrostatic chuck 121b and the annular insulating member. In addition, at least one RF/DC electrode coupled to a radio frequency (RF) power source and/or a direct current (DC) power source may be disposed inside the ceramic member. In this case, at least one RF/DC electrode functions as the lower electrode. When a bias RF signal and/or DC signal is supplied to at least one RF/DC electrode, the RF/DC electrode is also referred to as a bias electrode. The conductive member of the base 121a and the at least one RF/DC electrode may function as a plurality of lower electrodes. Further, the electrostatic electrode may function as the lower electrode. Accordingly, the support member 120 includes at least one lower electrode.

The ring assembly 122 includes one or a plurality of annular members. In one embodiment, the one or more annular members include one or more edge rings and at least one cover ring. The edge ring is made of an electrically conductive material or an insulating material, and the cover ring is made of an insulating material. In the embodiment, the ring assembly 122 is a consumable ring that is an example of a consumable component to be replaced. Accordingly, the ring assembly 122 before use is stored in the mobile replacement apparatus 2 to be described later and replaced with the ring assembly 122 after use in the plasma processing chamber 110.

A plurality of, in the present embodiment, three lifters 123 are disposed to correspond to through-holes formed in the main body 121. Each lifter 123 includes three ring lift pins 123a for moving the ring assembly 122 on the annular region 120b (ring support surface) in the vertical direction and three substrate lift pins 123b for moving the substrate W on the central region 120a (substrate support surface) in the vertical direction. The lifter 123 also includes an actuator 124 for moving the ring lift pins 123a and the substrate lift pins 123b in the vertical direction. The actuator 124 may be commonly disposed for the ring lift pins 123a and the substrate lift pins 123b, or may be independently disposed for the ring lift pins 123a and the substrate lift pins 123b.

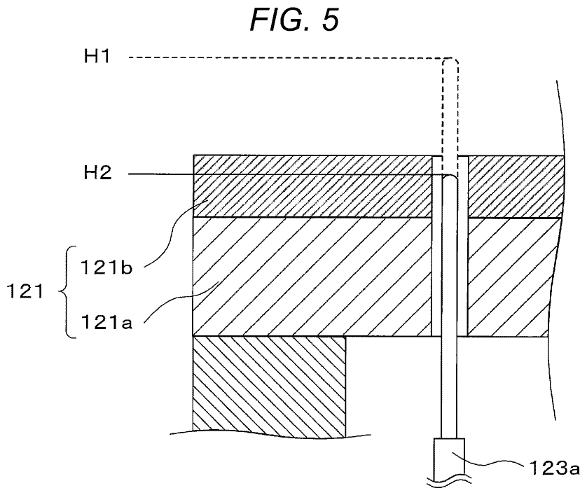

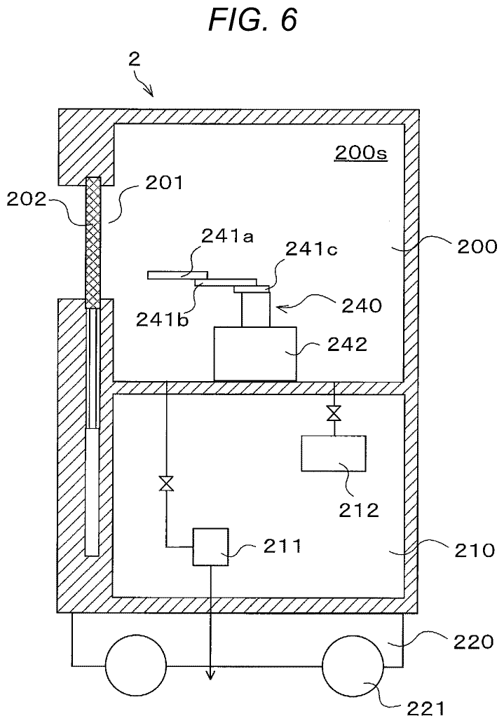

The actuator 124 moves each ring lift pin 123a between a transfer position H1 above the ring support surface and a standby position H2 below the ring support surface (see FIG. 5). At the transfer position H1, the ring assembly 122 is transferred between the transfer arms 71 of the transfer robot 70 and/or transfer arms 241 of a component replacement robot 240 to be described later. The standby position H2 is a position where a distal end of the ring lift pin 123a does not protrude from the ring support surface. Accordingly, the actuator 124 moves the ring lift pin 123a along an axial direction (vertical direction) to lift and lower the ring assembly 122 on the electrostatic chuck 121b. Examples of the actuator include an electric actuator, an air cylinder, and a motor.

The support member 120 may include a temperature control module configured to adjust at least one of the electrostatic chuck 121b, the ring assembly 122, and the substrate W to a target temperature. The temperature control module may include a heater, a heat transfer medium, a flow path, or a combination thereof. A heat transfer fluid, such as brine or gas, flows through the flow path. In one embodiment, a flow path is formed inside the base 121a, and one or a plurality of heaters are disposed inside the ceramic member of the electrostatic chuck 121b. The support member 120 may also include a heat transfer gas supply configured to supply a heat transfer gas (backside gas) to a gap between a rear surface of the substrate W and an upper surface of the electrostatic chuck 121b.

The plasma generator 130 is configured to generate plasma from at least one processing gas supplied into the plasma processing space 110s. The plasma generator 130 includes a gas introduction unit, a gas supply 132, and a power source 133.

The gas introduction unit includes a shower head 131. The shower head 131 is disposed above the support member 120. In one embodiment, the shower head 131 constitutes at least a portion of a ceiling portion of the plasma processing chamber 110.

The shower head 131 is configured to introduce at least one processing gas from the gas supply 132 into the plasma processing space 110s. The shower head 131 includes at least one gas supply port 131a, at least one gas diffusion chamber 131b, and a plurality of gas introduction ports 131c. The processing gas supplied from the gas supply 132 to the gas supply port 131a passes through the gas diffusion chamber 131b and is introduced into the plasma processing space 110s from the plurality of gas introduction ports 131c. The shower head 131 includes at least one upper electrode. The gas introduction unit may include, in addition to the shower head 131, one or a plurality of side gas injectors (SGI) that are attached to one or a plurality of openings formed in a sidewall of the plasma processing chamber 110. In the embodiment, the shower head 131 may be an example of the consumable component to be replaced. Accordingly, the shower head 131 before use may be stored in the mobile replacement apparatus 2 to be described later and replaced with the shower head 131 after use in the plasma processing chamber 110.

The gas supply 132 may include at least one gas source 132a and at least one flow rate controller 132b. In one embodiment, the gas supply 132 is configured to supply at least one processing gas from each corresponding gas source 132a to the shower head 131 via each corresponding flow rate controller 132b. That is, each gas source 132a may have a corresponding flow rate controller 132b, or in the alternative, one or more flow rate controllers 132b may be provided for a plurality of gas sources 132a. Each flow rate controller 132b may include, for example, a mass flow controller or a pressure-controlled flow rate controller. Further, the gas supply 132 may include at least one flow rate modulation device that modulates or pulses a flow rate of the at least one processing gas.

The power source 133 includes an RF power source 133a coupled to the plasma processing chamber 110 via at least one impedance matching circuit. The RF power source 133a is configured to supply at least one RF signal (RF power) to at least one lower electrode and/or at least one upper electrode. Accordingly, plasma is formed from the at least one processing gas supplied to the plasma processing space 110s. Supplying the bias RF signal to at least one lower electrode can generate a bias potential in the substrate W to attract an ionic component in the formed plasma to the substrate W.

In one embodiment, the RF power source 133a includes a first RF generator 133a1 and a second RF generator 133a2. The first RF generator 133al is coupled to at least one lower electrode and/or at least one upper electrode via the at least one impedance matching circuit, and is configured to generate a plasma generation source RF signal (source RF power). In one embodiment, the source RF signal has a frequency within a range from 10 MHz to 150 MHz. In one embodiment, the first RF generator 133al may be configured to generate a plurality of source RF signals having different frequencies. The generated one or more source RF signals are supplied to at least one lower electrode and/or at least one upper electrode.

The second RF generator 133a2 is coupled to the at least one lower electrode via the at least one impedance matching circuit and is configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 133a2 may be configured to generate a plurality of bias RF signals having different frequencies. The generated one or more bias RF signals are supplied to at least one lower electrode. Further, in various embodiments, at least one of the source RF signal and the bias RF signal may be pulsed.

The power source 133 may include a DC power source 133b coupled to the plasma processing chamber 110. The DC power source 133b includes a first DC generator 133b1 and a second DC generator 133b2. In one embodiment, the first DC generator 133b1 is connected to at least one lower electrode and is configured to generate a first DC signal. The generated first DC signal is applied to at least one lower electrode. In one embodiment, the second DC generator 133b2 is connected to at least one upper electrode and is configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator for generating the sequence of voltage pulses from a DC signal is connected between the first DC generator 133b1 and at least one lower electrode. Accordingly, the first DC generator 133b1 and the waveform generator form a voltage pulse generator. When the second DC generator 133b2 and the waveform generator form the voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first and second DC generators 133b1 and 133b2 may be provided in addition to the RF power source 133a, and the first DC generator 133b1 may be provided instead of the second RF generator 133a2.

In the illustrated example, a case where the plasma processing module 60 includes the capacitively-coupled plasma (CCP) plasma generator 130 is illustrated as an example.

However, the configuration of the plasma generator is not limited thereto, and may be inductively-coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The exhaust system 140 may be connected, for example, to a gas exhaust port 110e disposed at a bottom of the plasma processing chamber 110. The exhaust system 140 may include a pressure adjusting valve and a vacuum pump. Pressure inside the plasma processing space 110s is adjusted by the pressure adjusting valve. The vacuum pump may include a turbo molecular pump, a dry pump, or a combination thereof.

Returning to the description of the plasma processing system.

The mobile replacement apparatus 2 stores the consumable component before use such as the ring assembly 122 therein, and replaces the ring assembly 122 before use with the ring assembly 122 after use in the plasma processing module 60. As illustrated in FIG. 6, the mobile replacement apparatus 2 includes an upper chamber 200, a lower chamber 210, and a moving mechanism 220. The moving mechanism 220, the lower chamber 210, and the upper chamber 200 are stacked in this order.

As illustrated in FIGS. 1 and 6, the upper chamber 200 includes the component transfer port 201 connected to the second surface 110b of the plasma processing chamber 110 and a gate valve 202 that opens and closes the component transfer port 201. In addition, as illustrated in FIG. 1, the upper chamber 200 is provided with an opening 203 connected to a component storage portion 230 that stores a plurality of consumable components such as the ring assembly 122 and the shower head 131, and a gate valve 204 that opens and closes the opening 203. Accordingly, the mobile replacement apparatus 2 is connected to the plasma processing chamber 110 of the plasma processing module 60 via the second surface 110b, and the plasma processing space 110s and a replacement space 200s inside the upper chamber 200 communicate with each other through the component transfer port 201.

The component replacement robot 240 for transferring the ring assembly 122 or the like that is the consumable component is provided inside the upper chamber 200. The component replacement robot 240 is an articulated robot including a plurality of, for example, three transfer arms 241. Each of the three transfer arms 241 is pivotable. A transfer arm 241a at a distal end holds and transfers the consumable component. The transfer arm 241a at the distal end is also referred to as a so-called end effector. A transfer arm 241c at a proximal end is pivotably attached to a base 242. The component replacement robot 240 is configured to transfer the consumable component between the component storage portion 230 and the plasma processing module 60.

An exhaust system 211 and a gas supply system 212 are provided inside the lower chamber 210. The exhaust system 211 and the gas supply system 212 are connected to the replacement space 200s inside the upper chamber 200. In the mobile replacement apparatus 2, pressure inside the replacement space 200s can be adjusted by operations of the exhaust system 211 and the gas supply system 212.

The mobile replacement apparatus 2 is movable by the moving mechanism 220 to the front of any plasma processing module 60 whose consumable component is to be replaced. In an example, the moving mechanism 220 is provided with wheels 221, a power source such as a battery, a drive source, and a steering mechanism as illustrated in FIG. 6, and the configuration of the moving mechanism 220 is not particularly limited as long as the mobile replacement apparatus 2 can be moved. The mobile replacement apparatus 2 is moved to the front of any plasma processing module 60 by the moving mechanism 220 in this way, then is connected to the second surface 110b of the plasma processing module 60, and then the consumable component is replaced. Details of a method for replacing the consumable component will be described later.

The plasma processing system described above includes at least one controller 3 as described above. The controller 3 processes computer-executable instructions that cause the plasma processing system to execute various steps described in the disclosure. The controller 3 may be configured to control the elements of the plasma processing system to execute various steps described herein. In one embodiment, a part or all of the controllers 3 may be provided in the plasma processing system. The controller 3 may include a processor 3a1, a storage 3a2, and a communication interface 3a3. The controller 3 is implemented by, for example, a computer 2a. The processor 3al may read a program from the storage 3a2 and perform various control operations by executing the read program. The program may be stored in advance in the storage 3a2 or may be acquired via a medium when necessary. The acquired program is stored in the storage 3a2, read from the storage 3a2 by the processor 3al and executed. The medium may be various recording media readable by the computer 3a, or may be a communication line connected to the communication interface 3a3. The processor 3al may be a central processing unit (CPU). The storage 3a2 may include a random access memory (RAM), a read only memory (ROM), a hard disk drive (HDD), a solid state drive (SSD), or a combination thereof. The communication interface 3a3 may communicate with the plasma processing system via a communication line such as a local area network (LAN). Further, the storage medium may be temporary or non-temporary medium.

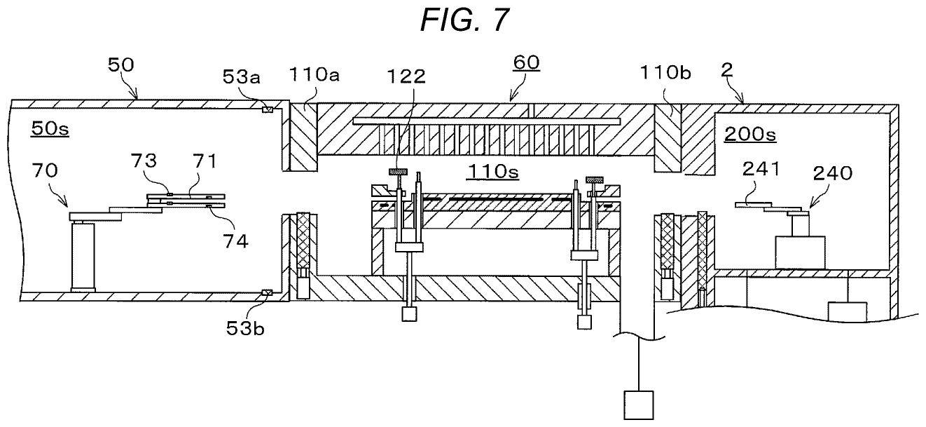

The plasma processing system according to the embodiment is implemented as described above. Next, a ring replacement sequence will be described as an example of the component replacement sequence performed using the plasma processing system. FIG. 7 is a cross-sectional view showing a state where the mobile replacement apparatus 2 is connected to the plasma processing module 60. In the following description, the ring assembly 122 is replaced as a consumable ring that is an example of the consumable component, and the component storage portion 230 and the component replacement robot 240 in the mobile replacement apparatus 2 respectively correspond to a ring storage portion and a ring replacement robot according to the technique of the disclosure. In an example, this ring replacement sequence is performed under control of the controller 3.

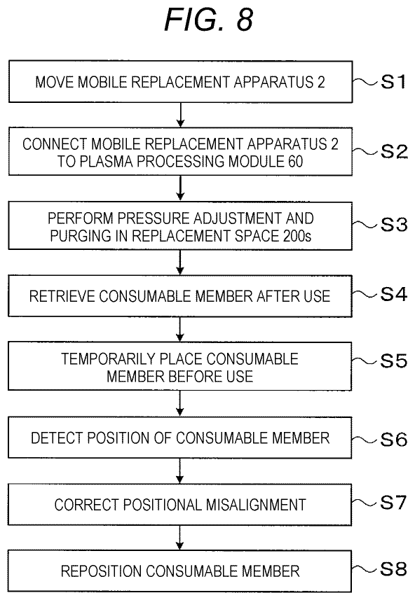

In the ring replacement sequence, first, the mobile replacement apparatus 2 is moved by the moving mechanism 220 to the front of the plasma processing module 60 whose ring assembly 122 is to be replaced (step S1 in FIG. 8).

Next, the mobile replacement apparatus 2 is connected to the second surface 110b of the plasma processing module 60 (step S2 in FIG. 8). The mobile replacement apparatus 2 is connected to the plasma processing module 60 using, for example, a fastening member or the like after a relative horizontal position of the mobile replacement apparatus 2 relative to the plasma processing module 60 is determined using, for example, a positioning pin.

Next, in a state where the gate valve 202 of the upper chamber 200 is closed and the plasma processing space 110s and the replacement space 200s are separated, pressure adjustment and purging in the replacement space 200s are performed (step S3 in FIG. 8). When the pressure inside the replacement space 200s substantially coincides with the pressure inside the plasma processing space 110s whose ring assembly 122 is to be replaced, the gate valve 202 of the upper chamber 200 and the gate valve 112 of the plasma processing chamber 110 are opened to establish communication between the plasma processing space 110s and the replacement space 200s.

When the plasma processing space 110s and the replacement space 200s communicate with each other, the ring assembly 122 after use in the plasma processing module 60 is then retrieved (step S4 in FIG. 8).

Specifically, first, each ring lift pin 123a is lifted from the standby position H2 to the transfer position H1, and the ring assembly 122 after use supported by the ring support surface of the support member 120 is lifted on the ring support surface.

Subsequently, the transfer arm 241 of the mobile replacement apparatus 2 is moved into the plasma processing space 110s and inserted below the ring assembly 122 after use lifted by the ring lift pin 123a.

Subsequently, the ring lift pin 123a is lowered from the transfer position H1 to the standby position H2, and accordingly, the ring assembly 122 after use is transferred from the ring lift pin 123a to the transfer arm 241 of the mobile replacement apparatus 2.

Finally, the transfer arm 241 holding the ring assembly 122 after use is moved to the replacement space 200s, and then the ring assembly 122 after use is transferred to the component storage portion 230 to complete retrieval of the ring assembly 122 after use.

Next, the ring assembly 122 before use is transferred into the plasma processing module 60 (step S5 in FIG. 8).

Specifically, first, the transfer arm 241 of the component replacement robot 240 enters the component storage portion 230 to hold the ring assembly 122 before use.

Subsequently, the transfer arm 241 holding the ring assembly 122 before use enters the plasma processing space 110s.

Subsequently, the ring lift pin 123a is lifted from the standby position H2 to the transfer position H1, and the ring assembly 122 before use is transferred from the transfer arm 241 to the ring lift pin 123a.

Thereafter, the transfer arm 241 is retracted into the replacement space 200s, and thus the transfer of the ring assembly 122 before use into the plasma processing module 60 is completed.

In this way, using the mobile replacement apparatus 2, the ring assembly 122 after use in the plasma processing module 60 can be appropriately replaced with the ring assembly 122 before use. At this time, the inside of the upper chamber 200 of the mobile replacement apparatus 2, that is, the replacement space 200s communicating with the plasma processing space 110s, is evacuated in advance to a vacuum level equal to that of the plasma processing space 110s (step S3). Therefore, since it is not required to expose, to the atmosphere, the plasma processing module 60 whose ring assembly 122 is to be replaced and parts can be replaced under reduced pressure, a vacuuming time after the replacement of the parts or a mean time between cleanings (MTBC) can be shortened.

However, since the mobile replacement apparatus 2 and the plasma processing module 60 are repeatedly attached and detached each time the parts are replaced, positional misalignment between the mobile replacement apparatus 2 and the plasma processing module 60 may occur due to docking (step S2) as described above. Therefore, due to such positional misalignment, a positional relationship between the support member 120 and the transfer arm 241 in the plasma processing module 60, that is, a relationship between a replacement position (planned placement position) of the ring assembly 122 and a transfer position by the transfer arm 241 becomes uncertain, and thus the ring assembly 122 may not be placed at a desired position.

Therefore, in the ring replacement sequence according to the technique of the disclosure, the ring assembly 122 before use transferred to the ring lift pin 123a by the transfer arm 241 is not placed on the support member 120 directly, and position adjustment is performed using the transfer robot 70 disposed in the vacuum transfer module 50. Accordingly, loading of the ring assembly 122 before use by the mobile replacement apparatus 2 (step S5) can be said to be a temporary placement step of the ring assembly 122 before use to the ring lift pin 123a (plasma processing module 60).

When the ring assembly 122 before use is transferred from the transfer arm 241 to the ring lift pin 123a, the transfer arm 71 of the transfer robot 70 then enters from the vacuum transfer space 50s into the plasma processing space 110s and is inserted below the ring assembly 122 before use held by the ring lift pin 123a.

At this time, a position of the ring assembly 122 before use in the plasma processing module 60 is detected based on measurement results from the first and second position detection sensors 73 and 74 attached to the end effector of the transfer arm 71 (step S6 in FIG. 8).

As an example, the first position detection sensor 73 disposed at the upper surface of the end effector detects the position of the ring assembly 122 before use on the ring lift pin 123a, and the second position detection sensor 74 disposed at the lower surface of the end effector detects a position of the support member 120. By combining the positions of the ring assembly 122 before use and the support member 120 obtained from the measurement results from the first and second position detection sensors 73 and 74, an amount of relative horizontal position misalignment of the ring assembly 122 before use relative to the support member 120 can be detected.

When the position of the ring assembly 122 before use is detected, the ring lift pin 123a is then lowered from the transfer position H1 to the standby position H2, and accordingly, the ring assembly 122 before use is transferred from the ring lift pin 123a to the transfer arm 71.

Next, the transfer arm 71 holding the ring assembly 122 before use is moved in the horizontal direction, and accordingly, the positional misalignment between the ring assembly 122 before use and the support member 120 detected in step S6 is corrected (step S7 in FIG. 8). The correction of the positional misalignment may be performed inside the plasma processing module 60 or inside the vacuum transfer module 50.

At this time, the vacuum transfer module 50 and the plasma processing module 60 are not attached and detached each time the parts are replaced, and a docking state thereof (a relationship of relative horizontal positions of the vacuum transfer module 50 and the plasma processing module 60) is fixed. Accordingly, since a positional relationship between the support member 120 and the transfer arm 71 in the plasma processing module 60, that is, a relationship between the replacement position (planned placement position) of the ring assembly 122 and a transfer position by the transfer arm 71 is fixed, the ring assembly 122 can be appropriately positioned at the desired position.

Further, the position detection sensor 53 that can detect a relative horizontal position relationship of the ring assembly 122 relative to the substrate transfer port 52 is attached in the vacuum transfer module 50. Accordingly, the relative positional relationship between the vacuum transfer module 50 and the plasma processing module 60 can be grasped, and the positioning (step S7) of the ring assembly 122 can be performed more appropriately.

When the positional misalignment between the ring assembly 122 before use and the support member 120 is corrected, the ring assembly 122 before use is then placed on the ring support surface of the support member 120 (step S8 in FIG. 8).

Specifically, first, the ring lift pin 123a is lifted from the standby position H2 to the transfer position H1, and accordingly, the ring assembly 122 before use is transferred from the transfer arm 71 to the ring lift pin 123a.

Subsequently, the transfer arm 71 is retracted to the vacuum transfer space 50s.

Finally, the ring lift pin 123a holding the ring assembly 122 before use is lowered from the transfer position H1 to the standby position H2, and accordingly, the ring assembly 122 before use is placed from the ring lift pin 123a to the ring support surface.

When the ring assembly 122 is placed on the ring support surface, a series of the ring replacement sequence is completed.

As described above, according to the plasma processing system according to the technique of the disclosure, even when the positional misalignment due to the docking (step S2) occurs between the mobile replacement apparatus 2 and the plasma processing module 60 whose consumable component is to be replaced, such positional misalignment can be corrected by the transfer robot 70 of the vacuum transfer module 50, and the consumable component can be appropriately transferred to the desired position.

In general, the mobile replacement apparatus 2 that stores and transfers the consumable component is often implemented with emphasis on a payload capacity due to a wide variety of types of consumable components, positional accuracy related to transfer is not high, and therefore, by performing the position correction by the transfer robot 70 as in the present application, the consumable component can be transferred to the desired position regardless of transfer accuracy of such mobile replacement apparatuses 2.

As described above, in the plasma processing system according to the present application, it is not required to expose the plasma processing module 60 to the atmosphere when replacing the consumable component. Therefore, the replacement of the consumable component can be performed under reduced pressure (vacuum) or in a dry environment, and the vacuuming time after the replacement of the parts or the mean time between cleanings (MTBC) can be shortened.

Accordingly, according to the technique of the disclosure, a module that includes the consumable component to be replaced is not limited to a module that performs processing on the substrate W under reduced pressure as the plasma processing module 60 described above, and any substrate processing module can be selected. Similarly, a module connected to the substrate processing module is not limited to a module that transfers the substrate W under reduced pressure as the vacuum transfer module 50 described above, and any substrate transfer module that transfers the substrate W under atmospheric pressure or in a dry environment can be connected thereto.

Further, according to the present application, the consumable component after use can be retrieved by the transfer arm 241 of the mobile replacement apparatus 2 without passing through the vacuum transfer module 50 (step S4). Therefore, it is not required to bring the consumable component after use into the vacuum transfer module 50, and thus contamination of the vacuum transfer module 50 can be prevented. In addition, the transfer arm 71 of the vacuum transfer module 50 is not used for retrieving the consumable component after use and use of the transfer arm 71 for component replacement can be minimized to reduce an influence on a process in another plasma processing module 60.

The above embodiment has been described using an example in which the consumable component to be replaced is the ring assembly 122 (cover ring or focus ring) that is a consumable ring, and the type of the consumable component is not limited thereto. Specifically, for example, the shower head 131 described above or a deposition shield for preventing deposition from adhering to the sidewall of the plasma processing chamber 110 may be replaced as the consumable component by the mobile replacement apparatus 2 and the transfer arm 71.

For example, a second chamber for facilitating maintenance of the plasma processing chamber 110, more specifically, a second chamber disposed inside the plasma processing chamber 110 to define a processing space in the plasma processing chamber 110 as disclosed in JP2022-8057A may be replaced as the consumable component by the mobile replacement apparatus 2 and the transfer arm 71.

In this way, even when another consumable component is replaced, after the consumable component is temporarily loaded by the mobile replacement apparatus 2, the consumable component can be appropriately transferred to a desired position by performing positional misalignment correction by the transfer arm 71.

In the above-described embodiment, a location of the consumable component to be replaced is grasped using the first and second position detection sensors 73 and 74 attached to the transfer arm 71 of the transfer robot 70 and the position detection sensor 53 attached to the vacuum transfer module 50 to transfer the consumable component. However, the number and disposition of position detection sensors are not limited thereto, and another position detection sensor may be further provided at any position in the plasma processing system.

Specifically, for example, instead of or in addition to the position detection sensor 53 or the first and second position detection sensors 73 and 74, another position detection sensor may be attached to a ceiling surface of the plasma processing module 60 (plasma processing chamber 110). A configuration and a type of the other position detection sensor are not particularly limited as long as the position of the consumable component on the transfer arm can be specified. In this way, by disposing the other position detection sensor in the plasma processing module 60, the position of the consumable component can be more accurately specified during the component replacement sequence, and the positional misalignment correction (step S7) and the transfer to the desired position described above can be more accurately implemented.

In the above-described embodiment, the location of the consumable component to be replaced is grasped by both the first and second position detection sensors 73 and 74 provided at the transfer arm 71 of the transfer robot 70 and the position detection sensor 53 disposed in the vacuum transfer module 50. However, in order to detect the horizontal position of the consumable component, it is not always required to use both the first and second position detection sensors 73 and 74 and the position detection sensor 53, and the position detection may be performed using one thereof. Accordingly, in the technique according to the disclosure, the detection of the position of the consumable component may be performed inside the plasma processing module 60 (by the first and second position detection sensors 73 and 74), or may be performed inside the vacuum transfer module 50 (by the position detection sensor 53).

In the above-described embodiment, only the position of the consumable component is detected using the position detection sensor, and alternatively, an orientation in a rotation direction of the consumable component may be further detected in addition to the position of the consumable component. For example, when the consumable component is the ring assembly 122, the orientation in the rotational direction can be detected by checking a position of an orientation flat formed at the ring assembly 122.

In the above-described embodiment, the consumable component before use stored in the mobile replacement apparatus 2 is transferred to the transfer arm 241, the ring lift pin 123a, the transfer arm 71, and the ring lift pin 123a in this order to perform the component replacement sequence (see FIG. 8). In other words, the consumable component is transferred from the transfer arm 241 of the mobile replacement apparatus 2 to the transfer arm 71 of the vacuum transfer module 50 via the ring lift pin 123a.

However, the method for the component replacement sequence is not limited thereto, and the consumable component may be directly transferred from the transfer arm 241 to the transfer arm 71 without passing through the ring lift pin 123a.

In this case, by detecting the position of the consumable component on the transfer arm 241 by the first position detection sensor 73 provided at the transfer arm 71 and detecting the position of the support member 120 by the second position detection sensor 74 to grasp a relative positional relationship between the consumable component and the support member 120 based on such detection results, the consumable component can still be appropriately transferred to the desired position.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

1. A cluster tool, comprising:
a plasma processing apparatus;
a mobile replacement apparatus; and
control circuitry, wherein
the plasma processing apparatus includes:
a plasma processing module having a first surface and a second surface;
a vacuum transfer module connected to the plasma processing module via the first surface; and
a position detection sensor,
the plasma processing module includes:
a support member having a substrate support surface and a ring support surface;
a consumable ring disposed on the ring support surface; and
a plurality of lifter pins configured to move in a vertical direction between a transfer position above the ring support surface and a standby position below the ring support surface,
the vacuum transfer module includes a transfer robot configured to transfer the consumable ring between the plasma processing module and the vacuum transfer module,
the mobile replacement apparatus includes:
a ring storage portion configured to store the consumable ring; and
a ring replacement robot configured to transfer the consumable ring between the ring storage portion and the plasma processing module,
the control circuitry is configured to control the plasma processing apparatus and the mobile replacement apparatus to execute a ring replacement sequence, and
the ring replacement sequence includes:
connecting the mobile replacement apparatus to the plasma processing module via the second surface;
transferring the consumable ring in the ring storage portion to the plasma processing module by the ring replacement robot and placing the consumable ring on the plurality of lifter pins at the transfer position;
detecting a horizontal position of the consumable ring on the plurality of lifter pins by the position detection sensor;
adjusting the horizontal position of the consumable ring on the plurality of lifter pins by the transfer robot based on a position detection result from the position detection sensor; and
moving the plurality of lifter pins to the standby position and placing the consumable ring on the ring support surface.

2. The cluster tool according to claim 1, wherein
the second surface of the plasma processing module is on a side opposite to the first surface of the plasma processing module.

3. The cluster tool according to claim 1, wherein
the position detection sensor is attached to a transfer arm of the transfer robot.

4. The cluster tool according to claim 3, wherein
the position detection sensor includes a first detection sensor configured to detect a position of the consumable ring in the plasma processing module, and a second detection sensor configured to detect a position of the support member, and
the control circuitry is configured to determine a relative positional relationship between the consumable ring and the support member based on detection results from the first detection sensor and the second detection sensor.

5. The cluster tool according to claim 1, wherein
the position detection sensor is attached to the plasma processing module.

6. The cluster tool according to claim 1, wherein
the position detection sensor is attached to the vacuum transfer module.

7. The cluster tool according to claim 6, wherein
the position detection sensor is disposed between the plasma processing module and the vacuum transfer module.

8. The cluster tool according to claim 7, wherein
the position detection sensor includes a light emitting unit configured to emit light, and a light receiving unit configured to detect the light, and
the control circuitry is configured to determine a position of the consumable ring between the plasma processing module and the vacuum transfer module based on a detection result of the light by the light receiving unit.

9. A cluster tool, comprising:
a substrate processing apparatus,
a mobile replacement apparatus, and
control circuitry, wherein
the substrate processing apparatus includes:
a substrate processing module having a first surface and a second surface;
a substrate transfer module connected to the substrate processing module via the first surface; and
a position detection sensor,
the substrate processing module includes a consumable component,
the substrate transfer module includes a transfer robot configured to transfer a substrate between the substrate processing module and the substrate transfer module,
the mobile replacement apparatus includes:
a component storage portion configured to store the consumable component; and
a component replacement robot configured to transfer the consumable component between the component storage portion and the substrate processing module;
the control circuitry is configured to control the substrate processing apparatus and the mobile replacement apparatus to execute a component replacement sequence, and
the component replacement sequence includes:
connecting the mobile replacement apparatus to the substrate processing module via the second surface;
transferring the consumable component in the component storage portion to the substrate processing module by the component replacement robot;
detecting a position of the transferred consumable component by the position detection sensor; and
adjusting the position of the transferred consumable component by the transfer robot based on a position detection result from the position detection sensor.

10. The cluster tool according to claim 9, wherein
the second surface is on a side opposite to the first surface.

11. The cluster tool according to claim 9, wherein
the position detection sensor is attached to a transfer arm of the transfer robot.

12. The cluster tool according to claim 9, wherein
the position detection sensor is attached to the substrate transfer module.

13. A method, comprising:
connecting a mobile replacement apparatus to a plasma processing module via a second surface of the plasma processing module;
transferring a consumable ring from a ring storage portion of the mobile replacement apparatus to the plasma processing module using a ring replacement robot and placing the consumable ring on a plurality of lifter pins at a transfer position;
detecting a horizontal position of the consumable ring on the plurality of lifter pins using a position detection sensor;
adjusting the horizontal position of the consumable ring on the plurality of lifter pins using a transfer robot of a vacuum transfer module based on a detection result from the position detection sensor; and
moving the plurality of lifter pins to a standby position to place the consumable ring on a ring support surface of a support member in the plasma processing module.

14. The method according to claim 13, wherein
the vacuum transfer module is connected to the plasma processing module via a first surface of the plasma processing module.

15. The method according to claim 14, wherein
the second surface of the plasma processing module is on a side opposite to the first surface of the plasma processing module.

16. The method according to claim 13, wherein
the position detection sensor is attached to a transfer arm of the transfer robot.

17. The method according to claim 13, further comprising:
detecting, by a first detection sensor of the position detection sensor, a position of the consumable ring in the plasma processing module;
detecting, by a second detection sensor of the position detection sensor, a position of the support member, and
determining a relative positional relationship between the consumable ring and the support member based on detection results from the first detection sensor and the second detection sensor.

18. The method according to claim 13, wherein
the position detection sensor includes a light emitting unit configured to emit light, and a light receiving unit configured to detect the light, and
the method further comprising determining a position of the consumable ring between the plasma processing module and the vacuum transfer module based on a detection result of the light by the light receiving unit.

19. The method according to claim 13, further comprising evacuating an internal space of the mobile replacement apparatus to a vacuum state before the transferring.

20. The method according to claim 13, further comprising determining a relative positional relationship between the consumable ring and the support member based on the detection result, wherein the adjusting is performed based on the relative positional relationship.
